(19) United States
(12) Patent Application Publication
(10) Pub. No.: US 2024/0170446 A1
(43) Pub. Date: May 23, 2024

(54) ELECTRONIC DEVICE WITH COPPER AND OXIDE LAYERS IN CONTACT

(71) Applicant: STMicroelectronics International N.V., Geneva (CH)

(72) Inventors: Sandrine LHOSTIS, Theys (FR); Bassel AYOUB, Grenoble (FR); Laurent FREY, Grenoble (FR)

(73) Assignee: STMicroelectronics International N.V., Geneva (CH)

(21) Appl. No.: 18/508,071

(22) Filed: Nov. 13, 2023

(30) Foreign Application Priority Data
Nov. 22, 2022 (EP) 22306718.2
Mar. 10, 2023 (FR) 2302249

(51) Int. Cl. H01L 23/00

(52) U.S. Cl. CPC H01L 24/80; H01L 24/08; H01L 2224/08145; H01L 2224/80895; H01L 2224/80896

(57) ABSTRACT

The present description concerns a method of assembly of a first assembly layer comprising a first copper region at a first surface and of a second assembly layer comprising a second region made of oxide or of an oxidized metal at a second surface, wherein the first and second surfaces are assembled by means of a hybrid bonding such that the entire first copper region is placed into contact with the oxide or the oxidized metal of the second region.

### CROSS-REFERENCE TO RELATED APPLICATION(S)

This application claims the priority benefit of French patent application number 2302249, filed on Mar. 3, 2023, entitled “Dispositif électronique à couches de cuivre et d'oxyde en contact,” which is hereby incorporated by reference to the maximum extent allowable by law.

### BACKGROUND

### Technical Field

The present disclosure generally concerns electronic devices, for example optoelectronic devices, comprising structures formed of copper and oxide layers in contact.

### Description of the Related Art

The manufacturing of electronic devices, for example of optoelectronic devices, generally requires forming stacks of layers of different materials, for example layers of dielectric materials in contact with layers of metallic materials, as well as thermal treatments, for example anneals intended to stabilize the formed stacks.

For example, a stack of dielectric layers on metal layers may be implemented to form metallic optical filters, such as interference filters. Metallic optical filters may be intended to be assembled with optical sensors, such as image sensors.

However, the stacking of a dielectric layer, in particular made of oxide, for example of a silicon oxide, on a metal layer, in particular made of copper, may generate issues of lack of adherence, for example delamination phenomena at the interface, all the more when the stack is submitted to a thermal treatment.

### BRIEF SUMMARY

There exists a need to solve issues of lack of adherence between copper layers and layers made of oxide, or of oxidized metal, in electronic devices.

An embodiment overcomes all or part of the disadvantages of known electronic devices, in particular of known optoelectronic devices.

The embodiments in particular target metallic optical filters, or metal lenses, intended to be assembled to optical sensors, such as image sensors.

A specific application of the embodiments concerns optical sensors made in CMOS technology on a substrate, typically a silicon substrate.

The embodiments may also target current redistribution structures comprising copper in contact with an oxide or an oxidized metal.

An embodiment provides a method of assembly of a first assembly layer comprising a first copper region at a first surface and of a second assembly layer comprising a second region made of oxide or of an oxidized metal at a second surface, wherein the first and second surfaces are assembled by means of a hybrid bonding such that the entire first copper region is placed into contact with the oxide or the oxidized metal of the second region.

According to an embodiment, the first assembly layer is comprised in a first structure, for example a first chip or a first wafer, the second assembly layer is comprised in a second structure, for example a second chip or a second wafer, and the method comprises, before the hybrid bonding, the positioning of the first structure relative to the second structure.

According to an embodiment, the first assembly layer comprises, for example is, a continuous copper layer.

According to an embodiment, the first assembly layer comprises, at the first surface, for example is, a first structured layer comprising, in a plane parallel to the plane of the first surface, first portions made of a first dielectric material, for example of oxide or oxidized metal, in alternation with second copper portions.

According to an embodiment, the first structured layer is formed according to a damascene method, the first dielectric material being for example a silicon oxide.

According to an embodiment, the dimensions in the plane of the second copper portions are in the range from 600 nm to 10 μm, for example in the range from 600 nm to 5 μm.

According to an embodiment, the dimensions in the plane of the second copper portions are smaller than 600 nm, for example smaller than 300 nm, or smaller than 200 nm, for example equal to approximately 100 nm.

According to an embodiment, the second assembly layer comprises, for example is, a continuous layer of the oxide or of the oxidized metal.

According to an embodiment, the second assembly layer comprises, at the second surface, for example is, a second structured layer comprising, in a plane parallel to the plane of the second surface, third portions of the oxide or of the oxidized metal, in alternation with fourth portions made of a second dielectric material, for example of a silicon nitride.

According to an embodiment, before the hybrid bonding:
the first assembly layer is formed above a first substrate, and the second assembly layer is formed above a second substrate; and/or
the first and second surfaces are planarized, for example by chemical-mechanical polishing; and/or
a metal layer, for example a silicon layer, is oxidized to form the oxidized metal at the second surface.

According to an embodiment, the method further comprises, after the hybrid bonding, an anneal step, for example at a temperature of at least 200° C.

According to an embodiment, the second assembly layer comprises a third region of oxide or of oxidized metal at a third surface opposite to the second surface, and the method comprises the assembly of the second assembly layer with a third assembly layer, comprising a fourth copper region at a fourth surface, the third surface being assembled with the fourth surface by means of another hybrid bonding such that the entire fourth copper region is placed into contact with the oxide or the oxidized metal of the third region.

According to embodiments:
the second assembly layer comprises, at the third surface, a third structured layer comprising, in a plane parallel to the plane of the third surface, fifth portions of the oxide or of the oxidized metal, in alternation with sixth portions made of a second dielectric material, for example of a silicon nitride; and/or
the third assembly layer comprises at the fourth surface, for example is, a fourth structured layer comprising, in a plane parallel to the plane of the fourth surface, seventh portions made of a first dielectric material, for example of oxide or oxidized metal, in alternation with eighth copper portions; and/or
the third assembly layer is comprised in a third structure, for example a third chip or a third wafer, the method comprising, before the other hybrid bonding, the positioning of the third structure relative to the second structure; and/or
the third assembly layer is formed above a third substrate, before the other hybrid bonding; and/or
the third and fourth surfaces to be assembled are planarized, for example by chemical-mechanical polishing, before the other hybrid bonding.

An embodiment provides an electronic device comprising a first assembly layer comprising a first copper region at a first surface assembled by hybrid bonding to a second surface of a second assembly layer comprising a second region of oxide or of an oxidized metal, wherein the entire first copper region is in contact with the oxide or the oxidized metal of the second region.

According to an embodiment, the electronic device comprises a third assembly layer comprising a fourth copper region at the level of a fourth surface assembled by hybrid bonding to a third surface of the second assembly layer opposite to the second surface and comprising a third region of oxide or of oxidized metal, wherein the entire fourth copper region is in contact with the oxide or the oxidized metal of the third region.

According to an embodiment, the oxide or the oxidized metal comprise a silicon oxide, a silicon oxynitride, a silicon oxycarbonitride, or an oxidized amorphous silicon.

According to an embodiment, the assembly by hybrid bonding of the first assembly layer and of the second assembly layer is comprised in a filter, for example an interference filter, a plasmonic filter, an induced transmission filter, and/or a filter comprising an optical cavity such as a Fabry-Pérot cavity, in a lens, and/or in a current redistribution layer.

An embodiment provides an optical sensor comprising an electronic device selected from among the previously-described electronic devices.

### BRIEF DESCRIPTION OF THE SEVERAL VIEWS OF THE DRAWINGS

The foregoing features and advantages, as well as others, will be described in detail in the rest of the disclosure of specific embodiments given by way of illustration and not limitation with reference to the accompanying drawings, in which:

FIG. 1A is a partial and simplified cross-section view showing an example of an electronic device comprising an interference filter resting on a substrate;

FIG. 1B is a cross-section view obtained by scanning electron microscopy of an interference filter similar to the interference filter of FIG. 1A;

FIG. 2A, FIG. 2B, FIG. 2C, FIG. 2D, and FIG. 2E are partial and simplified cross-section views of structures corresponding to steps of an assembly method according to an embodiment;

FIG. 3A, FIG. 3B, FIG. 3C, FIG. 3D, FIG. 3E, FIG. 3F, FIG. 3G, and FIG. 3H are partial and simplified cross-section views of structures corresponding to steps of an assembly method according to another embodiment;

FIG. 4 schematically shows, in a cross-section view, an electronic device according to an embodiment;

FIG. 5 schematically shows, in a cross-section view, an electronic device according to another embodiment;

FIG. 6 schematically shows, in a cross-section view, an example of an induced transmission filter;

FIG. 7 schematically shows, in a cross-section view, an induced transmission filter of an electronic device according to an embodiment;

FIG. 8 shows curves of the variation of the transmission according to the wavelength of induced transmission filters; and

FIG. 9 is a TEM image which shows a detail of a plasmonic filter obtained by an assembly method according to an embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail. In particular, all the steps of the methods of manufacturing the electronic devices and of the assembly methods are not detailed, being implementable by usual methods of microelectronics. Further, the substrates, for example the optical sensors, are not described in detail, the described embodiments and implementation modes being compatible with usual manufacturings of such substrates.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front,” “back,” “top,” “bottom,” “left,” “right,” etc., or relative positions, such as terms “above,” “under,” “upper,” “lower,” etc., or to terms qualifying directions, such as terms “horizontal,” “vertical,” etc., it is referred, unless specified otherwise, to the orientation of the drawings.

Unless specified otherwise, the expressions “about,” “approximately,” “substantially,” and “in the order of” signify plus or minus 10%, preferably of plus or minus 5%.

Throughout the present disclosure, a length designates a dimension along a first direction, the X direction identified in the drawings, of a main plane XY of an electronic device, parallel to the planes of the different layers of this electronic device, a width designates a dimension along a second direction, the Y direction identified in the drawings, of the main plane. A thickness, a depth, or a height designate a dimension in a direction perpendicular, the Z direction identified in the drawings, to main plane XY. For example, the main plane may correspond, or be parallel, to the plane of a substrate of the electronic device.

Throughout the present disclosure, a structured layer designates a layer formed of an alternation, in main plane XY, of portions of different materials. The portions may be arranged to form a pattern, or structure, which is repeated periodically or not.

Throughout the present disclosure, a hybrid bonding is defined as being a bonding which combines a dielectric layer of oxide type with a metal of copper type incorporated in the oxide-type dielectric, generally to form interconnections. The hybrid bonding generally consists of a molecular bonding, which may be an oxide-to-oxide molecular bonding with a metal-to-metal contacting, which may be designated as a hybrid molecular bonding. The molecular bonding (or “direct bonding”) is induced by all the attractive electronic interaction forces between the atoms or molecules of two surfaces to be bonded and thus enables to fasten the two surfaces via a direct placing into contact without using a bonding material.

By oxidized metal, there is meant a metal such as copper having a surface, in particular the surface intended to be in contact with the copper, comprising an oxide layer corresponding at least to an atomic row of the oxidized metal, for example CuO or Cu₂O in the case of Cu, the thickness of the oxidized layer for example being in the order of 3 nm.

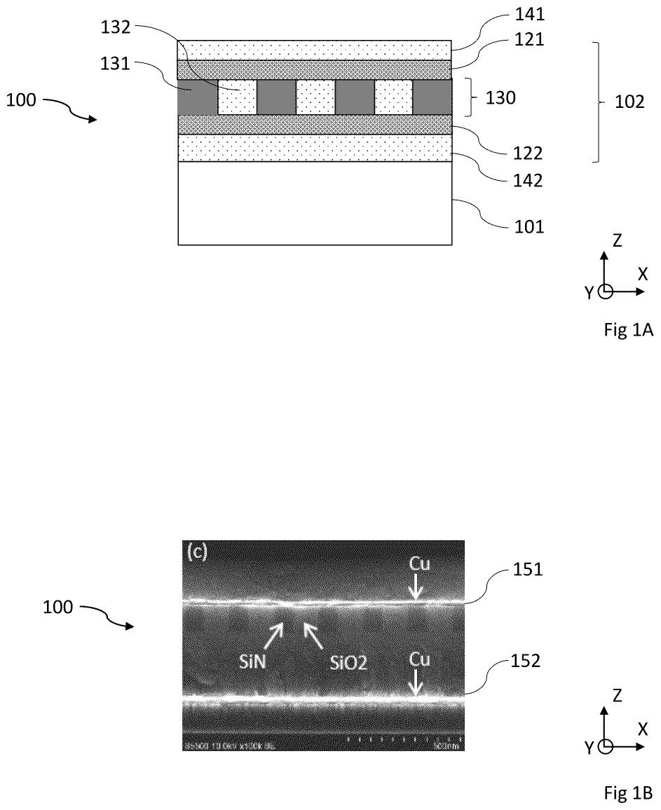

FIG. 1A is a partial and simplified cross-section view showing an example of an electronic device 100 comprising an interference filter 102 resting on a substrate 101. FIG. 1B is a cross-section view obtained by scanning electron microscopy (MEB) of an interference filter similar to the interference filter 102 of FIG. 1A.

Electronic device 100 is an optoelectronic device, and interference filter 102 is of the type comprising a Fabry-Pérot cavity.

Substrate 101 may correspond to an optical sensor, or an image sensor, comprising at least one photodetector, for example at least one photodiode, as well as an interconnection structure (not shown in FIG. 1A). Interference filter 102 is preferably positioned in front of a photodetector (not shown in FIG. 1A).

Substrate 101 may be based on silicon, and comprise at least one electronic circuit made in CMOS technology with a lower portion formed of electronic components, for example transistors, (photo)diodes, and/or capacitors, and an upper portion comprising a plurality of interconnection levels.

Interference filter 102 comprises two layers made of a metallic material 121, 122 forming semi-reflective mirrors spaced apart from each other by a layer said to be structured 130.

Structured layer 130 is formed of an alternation, in a plane XY parallel to semi-reflective mirrors 121, 122 and to substrate 101, of first portions 131 of a first dielectric material having a first low refraction index and of second portions 132 of a second dielectric material having a second high refraction index, greater than the first refraction index. The first and second portions are arranged to form a pattern, or structure, which is repeated periodically or not. For example, each second portion 132 of the second dielectric material is located between two first portions 131 of the first dielectric material in plane XY. It thus is not a superposition of layers of two different mediums along axis Z.

The lengths, and the widths, of the first and second portions are in the order of from a few tens of nanometers to a few hundreds of nanometers. It can be spoken of a “nanostructured” filter. The lengths, and/or the widths, of the first portions are not necessarily equal to the lengths, and/or to the widths, of the second portions.

In the shown example, the first and second portions substantially have the same thickness. In other words, structured layer 130 has a substantially constant thickness.

The layers of metallic material 121, 122 are themselves sandwiched between two layers 141, 142 which are, in the shown example, made of the second dielectric material. As a variant, the two layers 141, 142 could be made of a third dielectric material.

In the shown example, the metallic material is copper (Cu), the first dielectric material is silicon dioxide (SiO₂), and the second dielectric material is a silicon nitride (SiN).

Interference filter 102 is typically manufactured by implementing sequential depositions to form the different layers, as well as etchings, particularly to form the structured layer, and, possibly, polishing steps. The depositions are for example chemical vapor depositions (CVD) and/or physical vapor depositions (PVD).

A phenomenon observed during the manufacturing of this type of interference filter is a lack of adherence, for example a delamination phenomenon, at each interface 151, 152 between the copper layer and the structured layer, in particular between the copper layer and the silicon dioxide, as can be seen in FIG. 1B. This phenomenon may be, in particular, more critical at the lower interface 152 between the Cu and the SiO₂. This lack of adherence is exacerbated when the electronic device undergoes a thermal treatment, such as an anneal, particularly to integrate the interference filter to a substrate, such as an optical sensor. An example of thermal treatment is an anneal at approximately 400° C. for approximately 2 hours. This lack of adherence may result in a degradation of the quality of the filter, and/or in a difficulty to integrate the filter to the substrate, for example if it is desired to limit the delamination phenomenon by decreasing the thermal budget undergone by the filter during the thermal treatment.

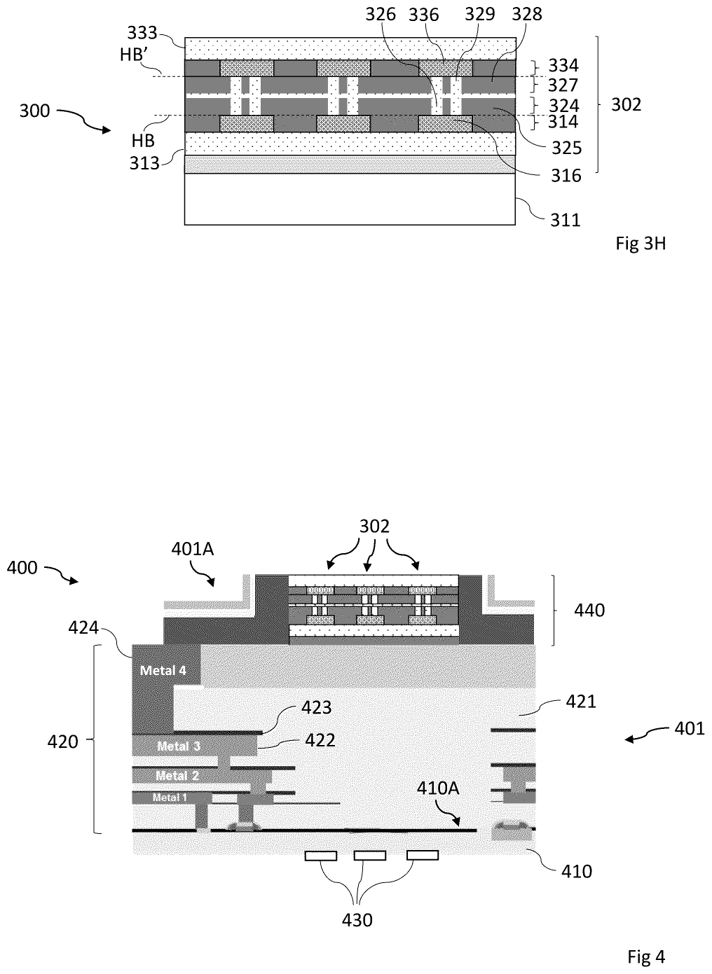

A solution to this lack of adherence is not to form a direct contact between the copper and the silicon oxide. A solution is to introduce a dielectric intermediate layer which is adapted to forming a silicon oxide barrier against the copper, for example a SiN layer, between the copper layer and the silicon oxide layer, as for example illustrated in FIG. 6 described hereafter. In the example of FIG. 1A, an intermediate SiN layer may be introduced between each copper layer 121, 122 and structured layer 130.

However, the fact of adding a dielectric intermediate layer, such as a SiN layer, has certain disadvantages, for example of modifying the properties of the filter, and/or of limiting the functionalities and performance of the filter. Indeed, SiN being a material having a refraction index different from SiO₂, in the case in point, higher, the phase shift undergone by the light in reflection and transmission at the Cu/SiN interface is not the same as at the Cu/SiO₂ interface. Thus, the fact of having to introduce a SiN layer in contact with the copper to improve the adherence imposes a specific phase shift and, more generally, limits the degrees of liberty in the filter design. The optical performance of the filter may thus be limited, for example by a lower transmission or a spectral response less compliant with the desired response, for example, less steep rising or falling edges. This may be possibly compensated for by adding additional dielectric layers in the stack, while keeping Cu/SiN interfaces, but this requires having a higher number of layers, and makes the filter more complex, and more expensive, to manufacture.

The inventors provide a method of manufacturing an electronic device comprising layers of copper and oxide, or of oxidized metal, in contact, and a corresponding electronic device, enabling to address the issues of lack of adherence and to overcome all or part of the previously-described disadvantages.

Embodiments of methods of manufacturing electronic devices comprising layers of copper and of oxide, or of oxidized metal, in contact, and of corresponding electronic devices, will be described hereafter. The described embodiments are non-limiting and different variants will occur to those skilled in the art based on the indications of the present description.

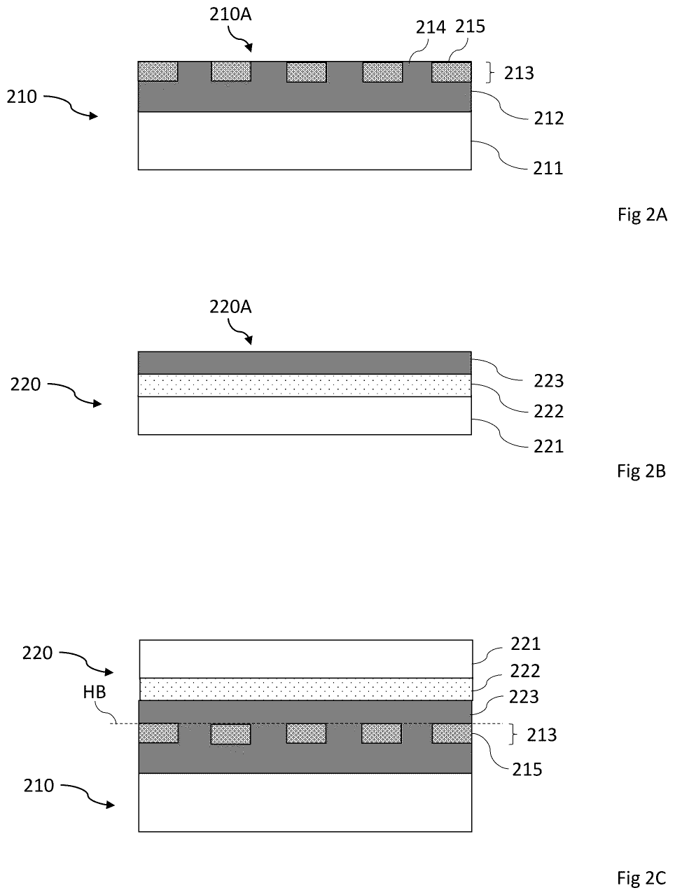

FIG. 2A, FIG. 2B, FIG. 2C, FIG. 2D, and FIG. 2E are partial and simplified cross-section views of structures corresponding to steps of an example of an assembly method according to an embodiment.

The assembly method may be included in an electronic device manufacturing method.

This example of assembly method may be adapted to manufacturing a plasmonic filter, for example intended to be assembled to an optical sensor. A plasmonic filter is an optical filter comprising one or a plurality of dielectric layers having metal pads (portions) formed therein, the pads having dimensions in the range from some ten nanometers to a few tens of nanometers.

As a variant, this example of assembly method may be adapted to manufacturing another structure, such as a current redistribution structure.

FIG. 2A shows a first initial structure 210 comprising a first substrate 211 having a first dielectric layer 212 made of a first dielectric material resting thereon.

First substrate 211 may be a simple support, or a manufacturing support, or correspond to an optical sensor, or an image sensor, for example similar to the substrate 101 described in relation with FIG. 1A.

For example, the first dielectric material is SiO₂. As a variant, the first dielectric material may be another silicon oxide, for example a silicon oxynitride (SiON), a silicon oxycarbide (SiOCN), or also a TiO₂/SiO₂ assembly.

First dielectric layer 212 is topped with a first structured layer 213 (first assembly layer) comprising, in plane XY, first portions 214 made of the first dielectric material in alternation with second copper portions 215 (first copper region).

The copper portions may be formed by a damascene method. A damascene method comprises the forming of cavities from a surface of a continuous layer made of a dielectric material, followed by a step of deposition of a metallic material to fill these cavities, and then generally a step of polishing (or “planarization”) of the surface to form a substantially planar surface where the dielectric material and metallic material outcrop. The forming of cavities generally comprises the etching of the continuous layer through an adapted pattern, for example formed by photolithography. The polishing step generally comprises a chemical-mechanical polishing (known under the term “CMP”).

Thus, first structured layer 213 may be formed by performing:
a partial etching, in depth and laterally, of the first dielectric layer (initially thicker, and without cavities), this partial etching being performed through a pattern adapted to forming cavities in alternation with non-etched portions forming the first portions 214 made of the first dielectric material; and then
a filling of the cavities by copper deposition to form the second copper portions 215; and, possibly,
a polishing step, for example by CMP, to have the first portions 214 and second portions 215 outcrop at the same level, corresponding to the level of an upper surface 210A (first surface) of first structure 210.

Preferably, the lengths, and the widths, of copper portions 215 (second portions) are in the order of from a few tens of nanometers to a few hundreds of nanometers, for example equal to approximately 100 nm.

The upper surface 210A of first structure 210 is preferably substantially planar, for example has a planeness in the order of some hundred nanometers at the scale of a 300-mm substrate (wafer).

FIG. 2B shows a second initial structure 220 comprising a second substrate 221 having an etch stop layer 222, itself topped with a second dielectric layer 223 (second assembly layer, second oxide region) made of the first dielectric material, resting thereon. Second dielectric layer 223 is flush with the upper surface 220A (second surface) of second structure 220.

Second substrate 221 is, for example, made of a silicon support.

For example, etch stop layer 222 may be made of a dielectric material, for example made of SiN, of an oxide, or of a doped material of the conductivity type different from that of the second substrate 221.

FIG. 2C shows a structure obtained at the end of the assembly of second structure 220, after having been flipped, with first structure 210. The assembly comprises a hybrid molecular bonding of the first 210A and second 220A surfaces, so that the second copper portions 215 are in contact with the first dielectric material of second dielectric layer 223. The obtained bonding is shown by a dotted line HB.

The hybrid molecular bonding is preferably followed by a thermal treatment, such as a anneal, for example at a temperature higher than or equal to 200° C.

FIG. 2D shows a structure obtained at the end of the removal of second substrate 221, for example by grinding and/or by thinning by wet etching down to etch stop layer 222.

FIG. 2E shows a structure obtained at the end of the removal of etch stop layer 222, for example by chemical-mechanical polishing (CMP).

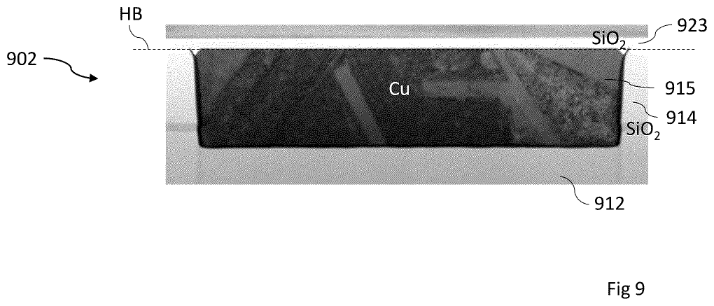

The electronic device 200 illustrated in FIG. 2E, is, for example, an optoelectronic device comprising an interference filter 202 of plasmonic filter type, on a substrate 211. Plasmonic filter 202 thus has copper portions 215 in contact with an oxide layer 223, without for a delamination phenomenon to have been observed at the interface between the copper and the oxide, as shown in FIG. 9 described hereafter.

The plasmonic filter of FIG. 2E comprises a single structured layer 213 with copper portions 215. This is no limiting. As a variant, the plasmonic filter could comprise a plurality of stacked structured layers, for example, another structured layer on the surface of oxide layer 223 opposite to the surface in contact with structured layer 213.

According to a variant, first dielectric layer 212 and/or first portions 214 may be made of a dielectric material different from the first dielectric material, that is, different from the dielectric material of second dielectric layer 223.

As a variant that may be combined with the previous variant, element 202 may represent a current redistribution structure (“RDL,” for Redistribution Layer) comprising copper portions in an oxide, an oxidized metal, and/or a polymer. For example, second layer 223 may be made of an oxide, for example of silicon oxide, and first dielectric layer 212 and/or first portions 214 may be made of a polymer. Those skilled in the art will be capable of adapting the hybrid bonding to bond the first polymer portions 214 and the second copper portions 215 to the second dielectric layer 223 made of oxide.

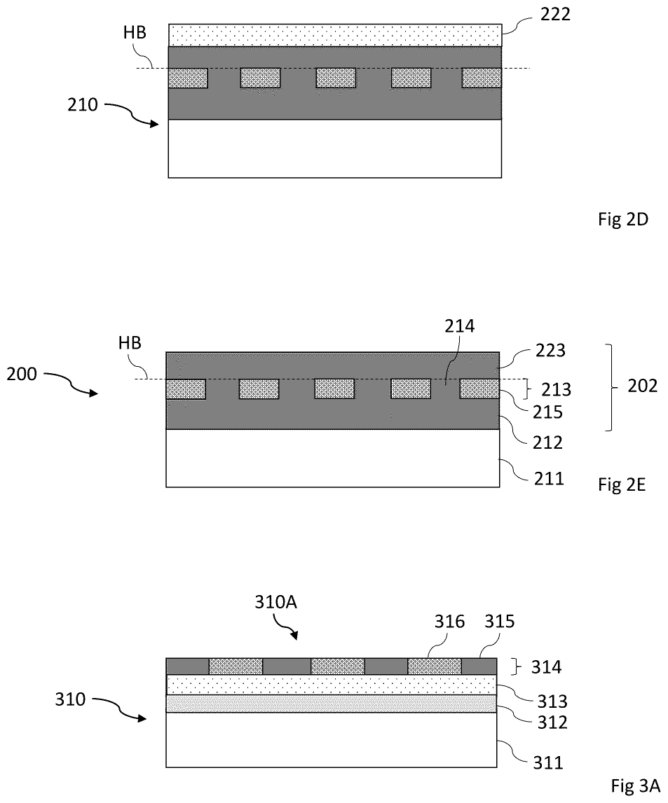

FIG. 3A, FIG. 3B, FIG. 3C, FIG. 3D, FIG. 3E, FIG. 3F, FIG. 3G, and FIG. 3H are partial and simplified cross-section views of structures corresponding to steps of an assembly method according to another embodiment.

The assembly method may be included in a method of manufacturing an electronic device.

This example of assembly method may be adapted to manufacturing an interference filter of the type comprising a Fabry-Pérot cavity, for example intended to be assembled with an optical sensor.

FIG. 3A shows a first initial structure 310 comprising a first substrate 311 having a first dielectric layer 312 made of a third dielectric material, itself topped with a second dielectric layer 313 of a second dielectric material, resting thereon. A first structured layer 314 (first assembly layer) rests on second dielectric layer 313, and comprises, in plane XY, first portions 315 made of a first dielectric material in alternation with second copper portions 316 (first copper region). The first and second portions 315, 316 are flush with an upper surface 310A (first surface) of first structure 310.

First structured layer 314 may be obtained similarly to the first structured layer 213 of FIG. 2A.

First substrate 311 may be a simple support, or a manufacturing support, or correspond to an optical sensor, or an image sensor, for example similar to the substrate 101 described in relation with FIG. 1A.

FIG. 3B shows a second initial structure 320 comprising a second substrate 321 having a third dielectric layer 322 made of the third dielectric material topped with a fourth dielectric layer 323 made of the second dielectric material resting thereon.

Second substrate 321 is, for example, a silicon support.

Fourth dielectric layer 323 is topped with a second structured layer 324 (second assembly layer) comprising an alternation, in plane XY, of third portions 325 made of the first dielectric material (second oxide region) and of fourth portions 326 made of the second dielectric material, the third and fourth portions 325, 326 being flush with an upper surface 320A (second surface) of second structure 320.

Second structured layer 324 may be formed by performing:
a first partial etching, in depth and laterally, of fourth dielectric layer 323 (initially thicker and with no cavities), this first etching being performed through a pattern adapted to forming cavities in alternation with non-etched portions forming the fourth portions 326 made of the second dielectric material; and then
a first step of filling of the cavities by a deposition of the first dielectric material to form the third portions 325 made of the first dielectric material; and, possibly,
a first polishing step, to have the third and fourth portions 325, 326 outcrop at the same level, corresponding to the level of the upper surface 320A (second surface) of second structure 320.

Preferably, the first dielectric material has a first low refraction index and the second dielectric material has a second high refraction index, greater than the first refraction index.

For example, the first dielectric material is SiO₂. As a variant, the first dielectric material may be another silicon oxide, for example a silicon oxynitride (SiON), a silicon oxycarbide (SiOCN), or even another oxide.

For example, the second dielectric material is SiN, or an aluminum nitride (AlN), or another dielectric material having a second refraction index greater than the refraction index of SiO₂. As a variant, the second dielectric material may be a titanium dioxide (TiO₂) or alumina (Al₂O₃).

For example, the third dielectric material is SiN, AlN, a titanium dioxide (TiO₂), a hafnium dioxide (HfO₂), or a dielectric material having a third refraction index different from the second refraction index.

FIG. 3C shows a structure obtained at the end of the assembly of second structure 320, after having been flipped, with first structure 310.

The assembly comprises a hybrid molecular bonding of the first 310A et second 320A surfaces, so that the second copper portions 316 are in contact with the fourth portions 326 made of the second dielectric material and with a portion of the third portions 325 made of the first dielectric material. The obtained bonding is shown by a dotted line HB.

The hybrid molecular bonding is preferably followed by a thermal treatment, such as an anneal, for example at a temperature higher than or equal to 200° ° C.

FIG. 3D shows a structure obtained at the end of the removal of second substrate 321 and of the third dielectric layer 322 of second structure 320.

FIG. 3E and FIG. 3F correspond to the forming, on the second structured layer 324 of second structure 320, of a third structured layer 327 comprising an alternation, in plane XY, of fifth portions 328 made of the first dielectric material (third oxide regions) and of sixth portions 329 made of the second dielectric material flush with the same level corresponding to a third surface 320B of second structure 320 opposite to second surface 320A. Fifth portions 328 are, for example, formed vertically in line with third portions 325 to form thicker portions made of the first dielectric material, but this is not compulsory. Sixth portions 329 are, for example, formed vertically in line with fourth portions 326 to form thicker portions made of the second dielectric material, but this is not compulsory.

Third structured layer 327 may be formed similarly to second structured layer 324, by performing:
a second partial etching of fourth dielectric layer 323 through a pattern (not shown) adapted to forming second cavities CV in alternation with non-etched portions forming the sixth portions 329 made of the second dielectric material, for example (but not necessarily) vertically in line with fourth portions 326, where this second etching may also be partial in depth to keep a thin thickness of the fourth dielectric layer 323 on second structured layer 324 (FIG. 3E), or may be adapted to removing the entire thickness of fourth dielectric layer 323 outside of sixth portions 329; and then
a second step of filling of the second cavities with a deposit made of the first dielectric material to form the fifth portions 328 made of the first dielectric material (FIG. 3F); and possibly;
a second polishing step, to have the fifth and sixth portions 328, 329 outcrop at the same level, corresponding to the third surface 320B of the second structure 320.

Preferably, the proportion between the first and second dielectric materials in the third structured layer 327 is substantially equal to the proportion between the first and second dielectric materials in second structured layer 324.

The second partial etching is performed from the third surface 320B of the second structure 320 obtained after the removal of the second substrate 321 and of the third dielectric layer 322, shown in FIG. 3D.

FIG. 3G shows a structure at the end of the assembly, after having been flipped, of a third structure 330, similar to first structure 310, on the third surface 320B of second structure 320.

Third structure 330 comprises a third substrate 331 having a fifth dielectric layer 332 made of the third dielectric material, itself topped with a sixth dielectric layer 333 made of the second dielectric material, resting thereon.

Third structure 330 further comprises on the sixth dielectric layer 333, at a fourth surface 330A of said third structure, a fourth structured layer 334 (third assembly layer) comprising, in plane XY, seventh portions 335 made of the first dielectric material in alternation with eighth copper portions 336 (fourth copper region). The seventh and eighth portions 335, 336 are flush with the fourth surface 330A of the third structure 330. The fourth structured layer 334 may be obtained similarly to the first structured layer 213 of FIG. 2A.

The assembly comprises a hybrid molecular bonding of the third 320B and fourth 330A surfaces, so that the eighth copper portions 336 are in contact with the sixth portions 329 made of the second dielectric material and a portion of the fifth portions 328 made of the first dielectric material. Further, the eighth copper portions 336 are preferably in front of the second copper portions 316. This obtained bonding is shown by a dotted line HB′.

FIG. 3H shows a structure obtained at the end of the removal of third substrate 331 and of the fifth dielectric layer 332 of third structure 330.

The electronic device 300 illustrated in FIG. 3H is an optoelectronic device comprising an interference filter structure 302 of the type comprising a Fabry-Pérot cavity (three filters in the shown example), on a substrate 311. Each filter 302 thus has copper portions 316, 336 on both its sides, and in contact with portions 326, 329 made of the second dielectric material and portions made of the first dielectric material (oxide) 325, 328, and this, without for a delamination phenomenon to be observed at the interface between the copper and the oxide.

Copper portions 316, 336 form semi-reflective mirrors, and the first and fourth structured layers 314, 334 are sandwiched between two layers 313, 333 (second and sixth dielectric layers) made of the second dielectric material. Preferably, the lengths, and the widths, of copper portions 316, 336 are in the range from 600 nm to 10 μm, for example from 600 nm to 5 μm.

In the shown example, the second and third structured layers 324, 327 have a substantially constant thickness.

The lengths, and the widths, of the fourth and sixth portions 326, 329 made of the second dielectric material are in the order of from a few tens of nanometers to a few hundreds of nanometers (nanostructured filters). For example, the fourth and sixth portions 326, 329 each have a substantially square cross-section with a side length in the range from 50 to 150 nm, for example equal to approximately 60 nm. The pitch between two of these nanostructures is for example in the range from 200 to 300 nm for an optical filter centered in the visible range or near-infrared (for example wavelengths between 600 and 950 nm). For example, the volume of the first dielectric material in each of the second and third structured layers 324, 327 amounts to approximately 91% of the total volume and the volume of the second dielectric material amounts to approximately 9% of the total volume.

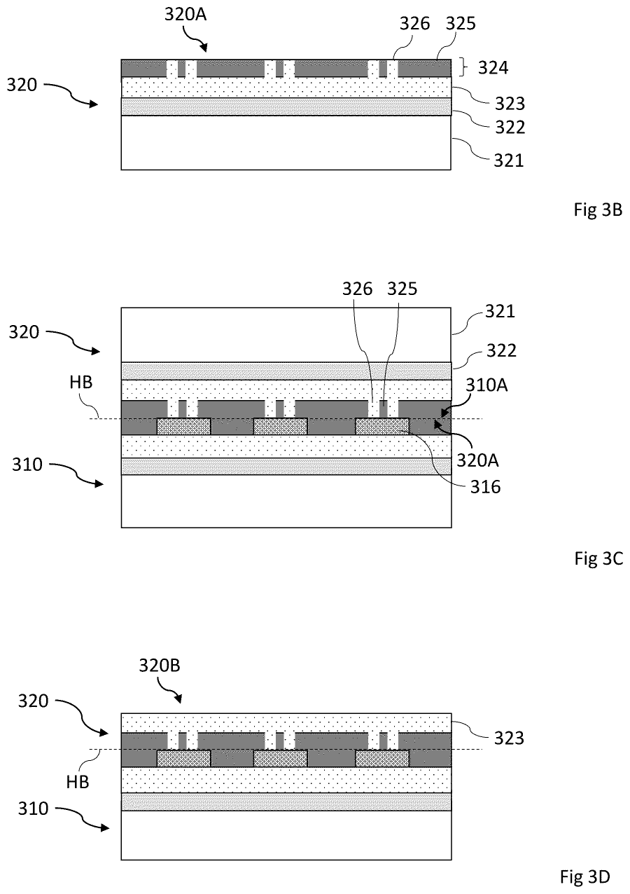

FIG. 4 schematically shows, in a cross-section view, an electronic device 400 according to an embodiment. Electronic device 400 is an optoelectronic device comprising a filter structure, similar to the interference filter structure 302 of FIG. 3H, assembled to a substrate 401.

For example, the structure of interference filters 302 of FIG. 3H is separated from its substrate 311, then assembled at the level of an upper surface 401A of substrate 401. Preferably, the upper surface 401A of substrate 401 is planar, for example has a planeness in the order of some hundred nanometers at the scale of a 300-mm substrate (wafer).

As a variant, interference filter 302 of FIG. 3H is formed directly on substrate 401, which then corresponds to substrate 311.

Substrate 401 corresponds to an optical sensor comprising a plurality of photodetectors 430, for example a plurality of photodiodes.

Substrate 401 comprises a layer 410, for example made of silicon, as well as electronic components, for example transistors, photodiodes, and/or capacitors, at an upper surface 410A of layer 410, and an interconnection structure 420 above this upper surface.

The shown interconnection structure 420 comprises a dielectric layer 421 having a plurality of metal levels coupled together (Metal 1, Metal 2, Metal 3), for example made of copper, formed therein, each metal level comprising a network of electric tracks 422 insulated by insulating layers 423. There has further been shown a fourth metallization level 424 (Metal 4), for example made of aluminum (Al), comprising a connection to the outside of “pad” or contact pad type, as well as passivation layers 440 above interconnection structure 420. Other interconnection structures may be envisaged.

Each interference filter 302 is located substantially vertically in line with a photodetector 430, for example with a photodiode.

In the shown example, insulating layers 423 do not extend above the photodetectors, for example to obtain better optical properties. In other examples, particularly for a single-wavelength filter, all or part of the insulating layers and/or of the passivation layer may extend between the filter and the photodetector, preferably according to defined thicknesses, for example to increase the transmission of light at the wavelength of the filter.

According to an example of manufacturing, once the metal levels have been formed on layer 410, a planarization of substrate 401 is performed so as to have a planar upper surface 401A. Interference filter structure 302 is manufactured by an assembly method according to an embodiment, either directly on the planarized substrate 401, or on a manufacturing substrate which is then removed, after which filter structure 302 is transferred onto the planarized substrate 401. Then, a deposition of passivation layers 440 is performed on the substrate/structure assembly, which is then opened above filter structure 302 and above contact pad 424 (metal 4).

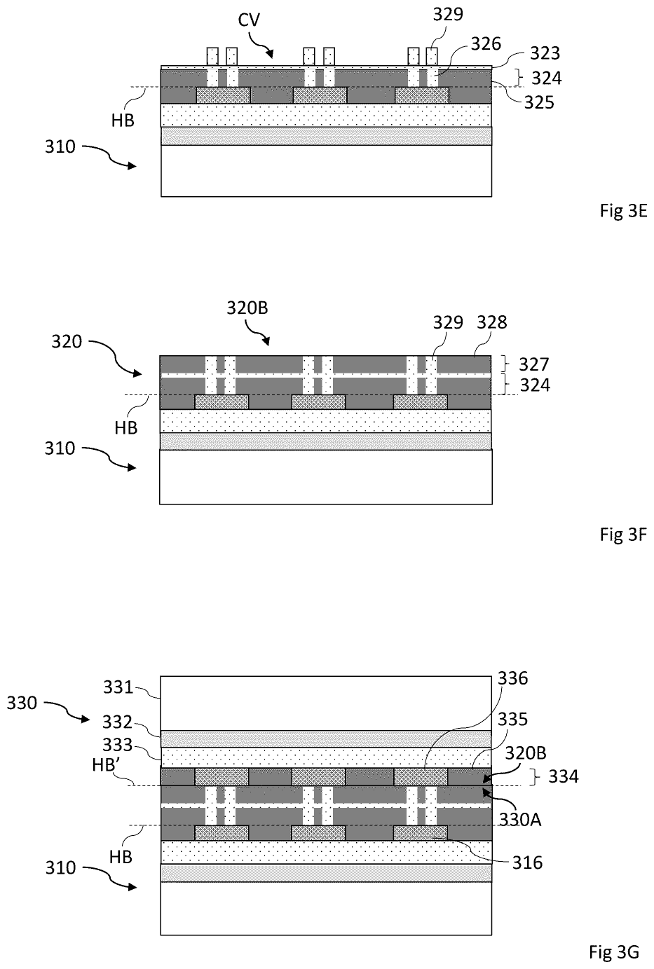

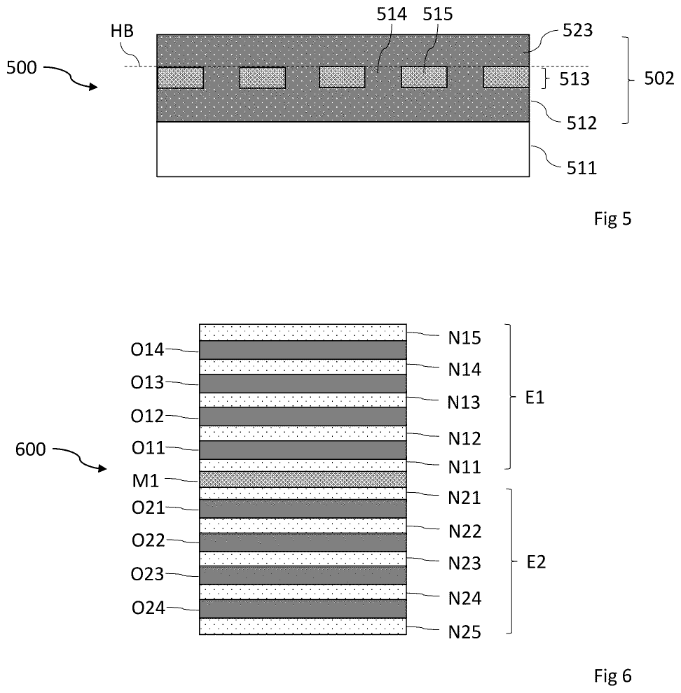

As a variant, electronic device 400 may comprise one (a plurality of) interference filter(s) similar to the interference filter 202 of FIG. 2E, or an induced transmission filter, for example the filter 502 of FIG. 5 described further on, or the filter 702 of FIG. 7 described further on. More generally, the electronic device may comprise at least one filter or a metal lens comprising a first assembly layer comprising a first copper region assembled by hybrid bonding to a second assembly layer comprising a second region of oxide or of an oxidized metal, so that the first copper region is in contact with the second region of oxide or of an oxidized metal.

FIG. 5 schematically shows, in a cross-section view, an electronic device 500 according to another embodiment. Electronic device 500 is an optoelectronic device comprising an induced transmission filter 502 resting on a substrate 511, which may be similar to the substrate 211 of FIG. 2E.

An induced transmission filter is defined as being a filter comprising at least one metal layer and dielectric layers under and above the metal layer, among which dielectric layers with high (second dielectric material) and low (first dielectric material) refraction indexes, where the number and the thickness of these layers may vary according to the targeted application. This filter structure is generally designed to maximize the transmission of the filter at a given wavelength. For this purpose, the alternations of dielectric layers with high and low refraction indexes above and under the metal layer are calculated to be used as impedance matching layers between the incident medium and the metal layer, and between the metal layer and the emerging medium.

The first dielectric material may be of oxidized silicon type, for example oxidized amorphous silicon, or SiO₂. The second dielectric material may be SiN.

The induced transmission filter differs from the interference filter 202 of plasmonic filter type of FIG. 2E mainly in that the induced transmission filter implements either a continuous metal layer (FIG. 7), or metal pads (portions) of great length, and of great width (FIG. 5), typically in the order of the wavelength, for example of a plurality of micrometers, while the lengths and the widths of the metal pads (portions) for a plasmonic filter are in the range from some ten nanometers to a few hundreds of nanometers.

The induced transmission filter 502 may be formed by steps similar to those described in relation with FIGS. 2A to 2E.

The induced transmission filter 502 of FIG. 5 exhibits copper portions 515, in alternation with portions 514 made of SiO₂ or of oxidized amorphous silicon and on a layer 512 made of SiO₂ or of oxidized amorphous silicon, copper portions 515 also being in contact with a layer 523 made of SiO₂ or of oxidized amorphous silicon, without for a delamination phenomenon to be observed at the interface between the copper and the SiO₂ or the oxidized silicon.

The induced transmission filter 502 thus formed for example enables to advantageously replace a silver layer, generally used in this type of filter, with a copper layer, better adapted in a CMOS-type manufacturing.

Further, an induced transmission filter generally comprises more than one dielectric layer on either side of the metal layer, as illustrated in FIGS. 6 and 7.

FIG. 6 schematically shows, in a cross-section view, an example of induced transmission filter 600, where there is no direct contact between a copper layer and an oxide layer. Each of the surfaces of copper layer M1 is in contact with a layer N11, N21 made of SiN, called spacer layer, coated with a layer O11, O21 made of SiO₂, itself coated with a layer N12, N22 made of SiN coated with layer O12, O22 made of SiO₂, etc. A stack E1, E2 of SiN layers alternating with SiO₂ layers has thus been formed on either side of copper layer M1, as indicated in table 1 hereafter.

The materials forming the layers of the induced transmission filter 600 of FIG. 6 and their thicknesses are gathered in table 1 hereafter.

TABLE 1

| Layer reference | Material | Thickness (nm) |
|---|---|---|
| N15 | SiN | 119 |
| O14 | SiO₂ | 162 |
| N14 | SiN | 119 |
| 013 | SiO₂ | 162 |
| N13 | SiN | 119 |
| O12 | SiO₂ | 162 |
| N12 | SiN | 119 |
| O11 | SiO₂ | 162 |
| N11 | SiN | 98 |
| M1 | Cu | 50 |
| N21 | SiN | 98 |
| O21 | SiO₂ | 162 |
| N22 | SiN | 119 |
| O22 | SiO₂ | 162 |
| N23 | SiN | 119 |
| O23 | SiO₂ | 162 |
| N24 | SiN | 119 |
| O24 | SiO₂ | 192 |
| N25 | SiN | 119 |

FIG. 7 schematically shows, in a cross-section view, an induced transmission filter 700 of an electronic device according to an embodiment, where there is a direct contact between a copper layer and an oxide layer. Thus, each of the surfaces of copper layer M2 is in contact with a layer O31, O41 made of SiO₂ coated with a layer N31, N41 made of SiN, called spacer layer, itself coated with a layer O32, O42 made of SiO₂ coated with a layer N32, N42 made of SiN, etc. A stack E3, E4 of SiO₂ layers alternating with SiN layers has thus been formed on either side of copper layer M2, as indicated in table 2 hereafter.

The materials forming the layers of the induced transmission filter 700 of FIG. 7 and their thicknesses are gathered in table 2 hereafter.

TABLE 2

| Layer reference | Material | Thickness (nm) |
|---|---|---|
| N35 | SiN | 119 |
| O35 | SiO₂ | 162 |
| N34 | SiN | 119 |
| O34 | SiO₂ | 162 |
| N33 | SiN | 119 |
| O33 | SiO₂ | 162 |
| N32 | SiN | 119 |
| O32 | SiO₂ | 162 |
| N31 | SiN | 119 |
| O31 | SiO₂ | 303 |
| M2 | Cu | 50 |
| O41 | SiO₂ | 303 |
| N41 | SiN | 119 |
| O42 | SiO₂ | 162 |
| N42 | SiN | 119 |
| O43 | SiO₂ | 162 |
| N43 | SiN | 119 |
| O44 | SiO₂ | 162 |
| N44 | SiN | 119 |
| O45 | SiO₂ | 162 |
| N45 | SiN | 119 |

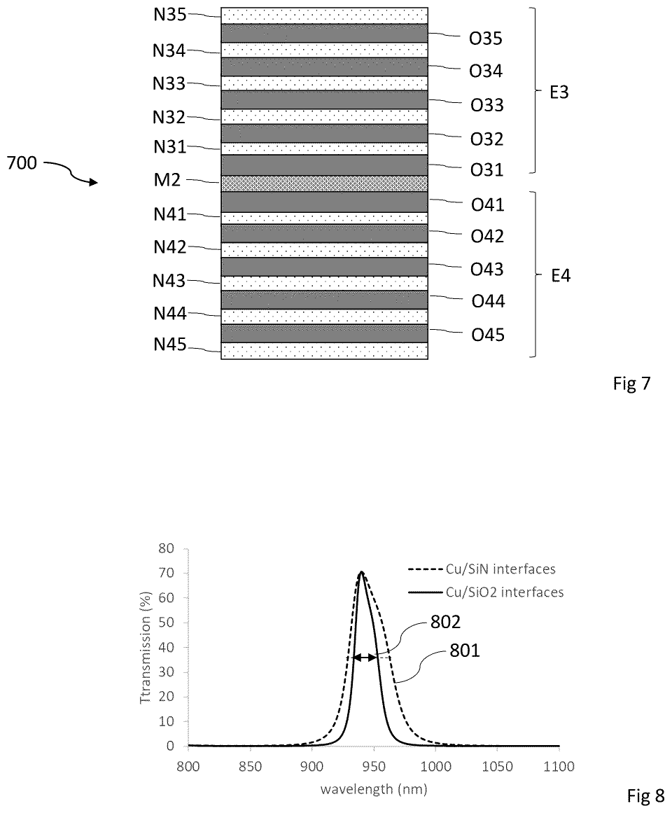

FIG. 8 shows curves of variation of the transmission according to the wavelength of induced transmission filters. Curve 801 in dotted lines corresponds to the filter 600 of FIG. 6, and curve 802 in full line corresponds to the filter 700 of FIG. 7.

Curves 801, 802 show that the fact of having a spacer layer made of oxide (SiO₂), with a low refraction index, allows a drastic decrease of the full width at half maximum (FWHM) of the transmission, in the order of 45% of decrease in the shown example, the full width at half maximum decreasing from approximately 35 nm to approximately 19 nm. A corollary of this decrease of the FWHM is a more significant decrease of the ambient light, for example in active imaging applications, such as distance measurement, inducing a better signal-to-noise ratio and a larger detection range.

Although the examples of FIGS. 5 to 7 show an induced transmission filter with a single metal layer, an induced transmission filter may comprise a plurality of metal layers, for example up to three metal layers.

FIG. 9 is an image taken by transmission electronic microscopy, or “TEM,” which shows a detail of a plasmonic filter 902, for example the plasmonic filter 202 of FIG. 2E.

Plasmonic filter 902 shows copper portions 915 between portions 914 made of SiO₂, the copper also being contact with a layer 923 made of SiO₂ without for a delamination phenomenon to be observed at the interface HB obtained by hybrid bonding between the copper and the SiO₂ of layer 923.

Examples of embodiments are summarized hereafter.

Example 1. Method of assembly of a first layer comprising a first copper region at a first surface and of a second layer comprising a second region of oxide or of an oxidized metal at a second surface, where the first and second surfaces are assembled by means of a hybrid bonding such that the entire first copper region is placed into contact with the oxide of the second region.

Example 2. Method according to example 1, wherein the oxide or the oxidized metal comprises a silicon oxide, or a silicon oxynitride.

Example 3. Method according to example 1 or 2, wherein the first layer is comprised in a first structure, for example a first chip or a first wafer, the second layer is comprised in a second structure, for example a second chip or a second wafer, and the method comprises, before the hybrid bonding, the positioning of the first structure relative to the second structure.

Example 4. Method according to any of examples 1 to 3, wherein before the hybrid bonding, the first layer is formed on a first substrate, and the second layer is formed on a second substrate.

Example 5. Method according to any of examples 1 to 4, wherein, before the hybrid bonding, the first and second surfaces to be assembled are planarized, for example by chemical-mechanical polishing.

Example 6. Method according to any of examples 1 to 5, wherein the first layer is a continuous copper layer.

Example 7. Method according to any of examples 1 to 5, wherein the first layer comprises a discontinuous copper layer, for example copper pads in a first dielectric layer, such as an oxide layer.

Example 8. Method according to any of examples 1 to 7, wherein the first layer is formed according to a damascene method, the first dielectric layer for example being a silicon dioxide layer.

Example 9. Method according to example 7 or 8, wherein the widths of the copper pads are in the range from 600 nm to 10 μm, for example from 600 nm to 5 μm.

Example 10. Method according to example 7 or 8, wherein the widths of the copper pads are smaller than 600 nm, for example smaller than 300 nm, or smaller than 200 nm, for example equal to approximately 100 nm.

Example 11. Method according to any of examples 1 to 10, wherein the second layer is a continuous layer of oxide or of oxidized metal.

Example 12. Method according to any of examples 1 to 10, wherein the second layer comprises a discontinuous layer of oxide or of oxidized metal, for example pads of oxide or of an oxidized metal between pillars made of a second dielectric material, for example a silicon nitride.

Example 13. Method according to any of examples 1 to 12, wherein the second layer is a multilayer comprising a layer of oxide or of oxidized metal and a layer of a third dielectric material, for example a silicon nitride, the layer of oxide or of oxidized metal being positioned on the layer of the third dielectric material.

Example 14. Method according to any of examples 1 to 13, further comprising, before the hybrid bonding, a step of oxidization of a metal layer, for example a silicon layer, to form the oxidized metal at the level of the second surface.

Example 15. Method according to any of examples 1 to 14, further comprising, after the hybrid bonding, an anneal step, for example at a temperature of at least 200° ° C.

Example 16. Method according to any of examples 1 to 15, where the second layer comprises a third region of the oxide or of the oxidized metal at the level of a third surface opposite to the second surface, and the method comprises the assembly of a third layer comprising a fourth copper region at the level of a fourth surface, with the second layer, the third surface being assembled with the fourth surface by means of a hybrid bonding so that the entire fourth region is placed into contact with the third region.

Example 17. Electronic device comprising a first layer assembled with a second layer, the first layer comprising a first copper region and the second layer comprising a second region of oxide or of an oxidized metal, where the entire first copper region is in contact with the oxide or the oxidized metal of the second region.

Example 18. Electronic device comprising a first layer and a second layer assembled according to the method of any of examples 1 to 16.

Example 19. Electronic device according to example 17 or 18, comprising a third layer assembled to the second layer.

Example 20. Electronic device according to any of examples 17 to 19, comprising a filter, an optical cavity, or a lens comprising the first copper region.

Example 21. Electronic device according to example 20, where the filter is a plasmonic filter, an interference filter, or an induced transmission filter, or the optical cavity is a Fabry-Perot cavity.

Example 22. Image sensor comprising an electronic device according to any of examples 17 to 21.

The applications of the embodiments encompass all the electronic devices in which an interface is desired to be formed between a copper layer and a layer of oxide, in particular a silicon oxide, such as SiO₂, SiON, or an oxidized metal, where the copper layer and/or the layer of oxide or of oxidized metal may be continuous or discontinuous.

The embodiments may in particular apply to the forming of metallic optical filters, or of metal lenses, intended to be assembled to optical sensors, such as image sensors.

An example of optical sensor may be an ambient light sensor (ALS), or an infrared band-pass filter.

The embodiments may also apply to current redistribution structures comprising copper in contact with an oxide or an oxidized metal.

Various embodiments and variants have been described. Those skilled in the art will understand that certain features of these various embodiments and variants may be combined, and other variants will occur to those skilled in the art. In particular, according to the targeted applications, the copper regions are not necessarily discontinuous (in the form of copper portions alternating with dielectric portions) and may, for example, correspond to continuous copper layers. Further, the number of layers, as well as their thicknesses and the selection of the first and second dielectric materials will occur to those skilled in the art according to the targeted application.

Finally, the practical implementation of the described embodiments and variants is within the abilities of those skilled in the art based on the functional indications given hereabove.

Method of assembly of a first assembly layer (213; 314; 513) may be summarized as including a first copper region (215; 316; 515) at a first surface (210A; 310A) and of a second assembly layer (223; 324, 327; 523) including a second region of oxide (223; 325) or of an oxidized metal (523) at a second surface (220A; 320A), wherein the first and second surfaces are assembled by means of a hybrid bonding such that the entire first copper region is placed into contact with the oxide or the oxidized metal of the second region.

The first assembly layer may include in a first structure (210; 310), a first chip or a first wafer, the second assembly layer may include in a second structure (220; 320), a second chip or a second wafer, and the method may include, before the hybrid bonding, the positioning of the first structure relative to the second structure.

The first assembly layer may include a continuous copper layer.

The first assembly layer may include, at the first surface (210A; 310A), a first structured layer (213; 314; 513) may include, in a plane (XY) parallel to the plane of the first surface, first portions (214; 315; 514) made of a first dielectric material, of oxide or oxidized metal, in alternation with second copper portions (215; 316; 515).

The first structured layer (213; 314; 513) may be formed according to a damascene method, the first dielectric material being a silicon oxide.

The dimensions in the plane (XY) of the second copper portions (316) may be in the range from 600 nm to 10 μm, in the range from 600 nm to 5 μm.

The dimensions in the plane (XY) of the second copper portions (215) may be smaller than 600 nm, smaller than 300 nm, or smaller than 200 nm, equal to approximately 100 nm.

The second assembly layer (223; 523) may include a continuous layer of the oxide or of the oxidized metal.

The second assembly layer may include, at the second surface (320A), a second structured layer (324) may include, in a plane (XY) parallel to the plane of the second surface, third portions (325) of the oxide or of the oxidized metal, in alternation with fourth portions (326) made of a second dielectric material, of a silicon nitride.

Before the hybrid bonding: the first assembly layer may be formed above a first substrate (211; 311; 511), and the second assembly layer may be formed above a second substrate (221; 321); and/or the first and second surfaces may be planarized, by chemical-mechanical polishing; and/or a metal layer, a silicon layer, may be oxidized to form the oxidized metal at the second surface.

Method may further include, after the hybrid bonding, an anneal step, at a temperature of at least 200° C.

The second assembly layer (324, 327) may include a third region (328) made of oxide or of oxidized metal at a third surface (320B) opposite to the second surface (320A), and the method may include the assembly of the second assembly layer with a third assembly layer (334), may include a fourth copper region (336) at a fourth surface (330A), the third surface being assembled with the fourth surface by means of another hybrid bonding such that the entire fourth copper region is placed into contact with the oxide or the oxidized metal of the third region.

The second assembly layer may include, at the third surface (320B), a third structured layer (327) may include, in a plane (XY) parallel to the plane of the third surface, fifth portions (328) of the oxide or of the oxidized metal, in alternation with sixth portions (329) made of a second dielectric material, of a silicon nitride; and/or the third assembly layer may include at the fourth surface (330A), a fourth structured layer (334) may include, in a plane (XY) parallel to the plane of the fourth surface, seventh portions (335) made of a first dielectric material, of oxide or oxidized metal, in alternation with eighth copper portions (336); and/or the third assembly layer may include in a third structure (330), a third chip or a third wafer, the method may include, before the other hybrid bonding, the positioning of the third structure relative to the second structure; and/or the third assembly layer is formed above a third substrate (331), before the other hybrid bonding; and/or the third and fourth surfaces to be assembled are planarized, by chemical-mechanical polishing, before the other hybrid bonding.

Electronic device (200; 300; 400; 500; 700) may be summarized as including a first assembly layer (213; 314; 513) including a first copper region (215; 316; 515) at a first surface (210A; 310A) assembled by hybrid bonding to a second surface (220A; 320A) of a second assembly layer (223; 324, 327; 523) including a second region (223; 325) of oxide or of an oxidized metal (523), wherein the entire first copper region is in contact with the oxide or the oxidized metal of the second region.

Electronic device may include a third assembly layer (334) including a fourth copper region (336) at the level of a fourth surface (330A) assembled by hybrid bonding to a third surface (320B) of the second assembly layer (324, 327) opposite to the second surface (320A) and may include a third region (328) of oxide or of oxidized metal, wherein the entire fourth copper region is in contact with the oxide or the oxidized metal of the third region.

The oxide or the oxidized metal may include a silicon oxide, a silicon oxynitride, a silicon oxycarbide, or an oxidized amorphous silicon.

The assembly by hybrid bonding of the first assembly layer and of the second assembly layer may include in a filter, an interference filter, a plasmonic filter, an induced transmission filter and/or a filter may include an optical cavity such as a Fabry-Pérot cavity, in a lens, and/or in a current redistribution layer.

Optical sensor may be summarized as including an electronic device.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
forming a first assembly layer by:
forming a first copper region having a first surface; and
forming a second assembly layer having a second surface by:
forming a second region of oxide or of an oxidized metal at the second surface;
hybrid bonding the first and second surfaces so the entire first copper region is in contact with the oxide or the oxidized metal of the second region.

2. The method according to claim 1, wherein the first assembly layer is comprised in a first structure, a first chip or a first wafer, the second assembly layer is comprised in a second structure, a second chip or a second wafer, and the method comprises, before the hybrid bonding, the positioning of the first structure relative to the second structure.

3. The method according to claim 1, wherein the first assembly layer comprises, a continuous copper layer.

4. The method according to claim 1, wherein the first assembly layer comprises, at the first surface, a first structured layer comprising, in a plane parallel to the plane of the first surface, first portions made of a first dielectric material, of oxide or oxidized metal, in alternation with second copper portions.

5. The method according to claim 4, wherein the first structured layer is formed according to a damascene method, the first dielectric material being a silicon oxide.

6. The method according to claim 4, wherein the dimensions in the plane of the second copper portions are in the range from 600 nm to 10 μm, in the range from 600 nm to 5 μm.

7. The method according to claim 4, wherein the dimensions in the plane of the second copper portions are smaller than 600 nm, smaller than 300 nm, or smaller than 200 nm, equal to approximately 100 nm.

8. The method according to claim 1, wherein the second assembly layer comprises, is, a continuous layer of the oxide or of the oxidized metal.

9. The method according to claim 1, wherein the second assembly layer comprises, at the second surface, a second structured layer comprising, in a plane parallel to the plane of the second surface, third portions of the oxide or of the oxidized metal, in alternation with fourth portions made of a second dielectric material, of a silicon nitride.

10. The method according to claim 1, wherein, before the hybrid bonding:
the first assembly layer is formed above a first substrate, and the second assembly layer is formed above a second substrate;
the first and second surfaces are planarized, by chemical-mechanical polishing; and
a metal layer, a silicon layer, is oxidized to form the oxidized metal at the second surface.

11. The method according to claim 1, further comprising, after the hybrid bonding, an anneal step, at a temperature of at least 200° C.

12. The method according to claim 1, wherein the second assembly layer comprises a third region made of oxide or of oxidized metal at a third surface opposite to the second surface, and the method comprises the assembly of the second assembly layer with a third assembly layer, comprising a fourth copper region at a fourth surface, the third surface being assembled with the fourth surface by means of another hybrid bonding such that the entire fourth copper region is placed into contact with the oxide or the oxidized metal of the third region.

13. The method according to claim 12, wherein:
the second assembly layer comprises, at the third surface, a third structured layer comprising, in a plane parallel to the plane of the third surface, fifth portions of the oxide or of the oxidized metal, in alternation with sixth portions made of a second dielectric material, of a silicon nitride;
the third assembly layer comprises at the fourth surface, a fourth structured layer comprising, in a plane parallel to the plane of the fourth surface, seventh portions made of a first dielectric material, of oxide or oxidized metal, in alternation with eighth copper portions;
the third assembly layer is comprised in a third structure, a third chip or a third wafer, the method comprising, before the other hybrid bonding, the positioning of the third structure relative to the second structure;
the third assembly layer is formed above a third substrate, before the other hybrid bonding;
the third and fourth surfaces to be assembled are planarized, by chemical-mechanical polishing, before the other hybrid bonding.

14. An electronic device, comprising:
a first assembly layer that includes:
a first copper region having a first surface;
a second assembly layer having a second surface hybrid bonded to the first surface, the second assembly layer including:
a second region of oxide or of an oxidized metal, wherein the entire first copper region is in contact with the oxide or the oxidized metal of the second region.

15. The electronic device according to claim 14, comprising a third assembly layer having a fourth copper region at a level of a fourth surface hybrid bonded to a third surface of the second assembly layer opposite to the second surface and comprising a third region of oxide or of oxidized metal, wherein the entire fourth copper region is in contact with the oxide or the oxidized metal of the third region.

16. The electronic device according to claim 14, wherein the oxide or the oxidized metal comprises a silicon oxide, a silicon oxynitride, a silicon oxycarbide, or an oxidized amorphous silicon.

17. The electronic device according to claim 14, wherein the assembly by hybrid bonding of the first assembly layer and of the second assembly layer is comprised in a filter, an interference filter, a plasmonic filter, an induced transmission filter, and a current redistribution layer.

18. An electronic device, comprising:
a filter having an optical Fabry-Pérot cavity, the filter including:
a first assembly layer that includes:
a first copper region having a first surface;
a second assembly layer having a second surface hybrid bonded to the first surface, the second assembly layer including:
a second region of a material with oxide, the first copper region is in contact with the material with oxide.

19. The electronic device of claim 18, wherein the filter includes a third assembly layer having a third copper region at a level of a third surface hybrid bonded to a fourth surface of the second assembly layer opposite to the second surface.

20. The electronic device of claim 19, comprising a fourth region of the material with oxide, wherein the entire third copper region is in contact with the material with oxide of the fourth region.
